(19) United States
(12) Patent Application Publication
(10) Pub. No.: US 2006/0139045 A1
(43) Pub. Date: Jun. 29, 2006

(54) Device and method for testing unpackaged semiconductor die

(76) Inventors: Wesley Gallagher, Chula Vista, CA (US); Dennis M. Sheredy, Yuma, AZ (US); Roy A. Darling, San Diego, CA (US)

Correspondence Address: Whit Bivens, Esq.;Musick, Peeler & Garrett, LLP, Suite 1900, 225 Broadway, San Diego, CA, 92101, US

(21) Appl. No.: 11/321,971

(22) Filed: Dec. 29, 2005

Related U.S. Application Data
(60) Provisional application No. 60/640,082, filed on Dec. 29, 2004.

(51) Int. Cl. G01R 31/02

(52) U.S. Cl. 324/754

(57) ABSTRACT

An apparatus and method for testing singulated unpackaged semiconductor die.

### CLAIM OF PRIORITY

This Application claims the benefit of U.S. Provisional Application No. 60/640,082

### FIELD OF THE INVENTION

This invention relates to semiconductor testing and more particularly to an apparatus and method for holding and establishing electrical communication with an unpackaged semiconductor die. More particularly, this invention relates to an apparatus and method suitable for establishing electrical communication with an unpackaged semiconductor die in the context of rapid and high volume testing of such dice including, without limitation, testing at extreme parametric conditions. The device and method is useful in the testing of known good semiconductor die (“KGD”).

### BACKGROUND OF THE INVENTION

An increasing number of customers of semiconductor products are requesting known good semiconductor die (“KGD”). KGD are unpackaged die that have the same quality and reliability as the equivalent packaged product. The KGD typically are either packaged in conventional packaging by the purchaser or are used in the manufacture of multi-chip modules.

Multi-chip modules are used in many consumer electronics applications such as computers, cellular phones, calculators, and watches. Such modules incorporate two or more semiconductor dice. Because the procedures for packaging semiconductor dice are complex and costly, combining multiple dice in a single module can provide the same capability as a circuit including each of the dice packaged singularly at a substantially reduced cost. Furthermore, packaging multiple die together in a single module can decrease the total size of the electronic circuitry in such consumer electronics resulting in smaller and lighter devices. If, however, a defective die is included in a multi-chip module, typically the entire module is discarded resulting in the loss of the other functional dice and the wasted resources consumed in the packaging of the multi-chip module. Accordingly, it is desirable to determine whether the dice to be incorporated into a multi-chip module are KGD.

In addition, equipment known in the art to test semiconductor devices often is not capable of or limits the testing of semiconductor devices at the extreme ends of the test parameters such as testing utilizing high voltage, high current, high frequency and low resistance.

Thus, there is a need for an apparatus and method for testing unpackaged semiconductor dice. Such an apparatus should be capable of reliably testing a large number of dice without degrading the test signal environment and without requiring frequent significant maintenance. Furthermore, such an apparatus and method should be able to interface with the type of automated equipment and assembly procedures found in the context of high volume semiconductor manufacturing.

U.S. Pat. No. 6,246,251 (the “'251 Patent”) discloses a test process and apparatus for testing singulated semiconductor die. The apparatus of the '251 patent comprises a plurality of test nests for receiving a singulated semiconductor die. Each test nest includes first and second portions that are moveable away from one another to receive the die. A probe card including at least one needle for electrically connecting to a first side of the semiconductor die is coupled to the first portion. The at least one needle is electrically connected to at least one first edge connector. At least one test unit for performing electrical tests on the semiconductor die is adapted to removably engage the at least one first edge connector.

The apparatus disclosed in the present application has several advantages not present in the apparatus disclosed in the '251 patent (hereinafter the “'251 apparatus”). First, in the '251 apparatus, the needles used to electrically connect to the semiconductor die are quite fragile and can easily be knocked out of alignment. Accordingly, the '251 apparatus requires substantial time-consuming maintenance.

Second, the use of needle contacts limits the test capability of the device. For example, when electrical tests involving high frequencies are conducted, the needles act as antennas and create substantial interference patterns that may render the test results meaningless. In addition, the '251 apparatus is limited in its ability to perform high voltage and high current testing with low leakage. Furthermore, the '251 apparatus is limited in its ability to test devices with very small geometries.

Third, the '251 apparatus makes two moveable connections between the die and the test equipment, the first being the needle-die connection and the second being the edge connector-testing equipment connection. Both connections are broken each time a tested die is removed from the test nest and a new die is inserted into the test nest. Thus, there are two points at which a poor connection can interfere with the testing process. Furthermore, the repetitive disconnecting and reconnecting causes significant flexing of the wires and circuit boards or other materials involved which results in fatigue and eventual failure of such materials further increasing the maintenance requirements of the '251 apparatus. Finally, if a poor connection is made either at the needle-die interface or at the edge connector-tester interface, the '251 apparatus is not easily adapted to opening such connections and reestablishing them in hopes of establishing a good connection.

### SUMMARY OF THE INVENTION

In accordance with the invention, a novel apparatus and process is provided that allows full parametric testing of bare die as if it were fully packaged, including standard DC parameters as well as switching speeds and avalanche testing for power devices and other high performance parameters for virtually all semiconductor devices. The design of the test assembly allows very accurate die placement for presenting the die to the tester interface. Further, in many embodiments of the invention, the only moving parts in the electrical pathway between the die and the test equipment are the contact tooling. Such tooling may include, but is not limited to, probe needles, cascade pyramid contacts, form factors, spring biased electrical contact probes such as those disclosed in U.S. Pat. No. 6,424,166 or any other known contact tooling that is compliant when contacting the die and will form an electrical connection when pressed into position with the die. One preferred embodiment uses spring biased electrical contact probes such as those disclosed in U.S. Pat. No. 6,424,166. Such probes are specifically designed to cycle through more than 500,000 contacts and releases. Accordingly, the failures resulting from material and wire flex and associated maintenance time are greatly reduced or eliminated. In addition, the ability of the plunger of the probe to be compressed within the barrel of the probe allows an array of such probes to make good contact with the surface of a die even if that die surface is uneven or not planar. In addition, the ability of the probe to be compressed results in the testing apparatus being somewhat self-calibrating within a certain range with respect to distance between the first and second probe cards when the apparatus is in a relatively closed position to contact a die.

Further, by eliminating the moveable contact between the edge connector and the tester, the number of faulty connections made that may interfere with the testing are greatly reduced in comparison with the prior art. In addition, the tester may be located within twelve inches of the test nest to further reduce resistance and noise. Furthermore, the disclosed embodiments are capable of accommodating a large contactor board allowing preconditioning electronics for the test signals to be mounted in very close proximity to the device under test. Further, in the event of an imperfect contact between the probes and the die, the apparatus can easily break and reestablish contact to ensure a good connection.

A preferred embodiment of a singulated semiconductor die testing apparatus in accordance with the invention may include:

a first platen;

a first test contact interface card attached to said first platen;

said first contact interface card having at least two electrically conductive traces adapted to establish electrical contact with test equipment;

a first set of test contact tooling attached to said first contact interface card having at least one compliant electrical contact electrically connected to one of said at least two conductive traces and adapted to contact a first surface of a singulated bare die and establish electrical contact between said first surface of said die and said one of said at least two conductive traces;

a second platen moveable with respect to said first platen between a substantially open position and a substantially closed position;

a second contact interface card attached to said second platen whereby said second contact interface card is between said first platen and said second platen;

said second contact interface card having at least one conductive trace electrically connected to at least one large spring biased electrical contact probe;

said large spring biased electrical contact probe adapted to establish electrical contact with a second of said at least two conductive traces on said first contact interface card;

a second set of contact tooling attached to said second contact interface card having at least one compliant electrical contact electrically connected to said at least one conductive trace and adapted to contact a second surface of a singulated bare die and establish electrical contact between said second surface of said die and said at least one conductive trace;

means for moving said second platen between an open position and a closed position and for guiding said second platen; and

a frame for supporting said first platen, said means for moving said second platen and for guiding said second platen.

In one embodiment of the apparatus, the moveable platen is moved from a substantially open position to a substantially closed position by either an electric motor, a plunger or pancake lift which may be driven either by compressed gas or liquid, or any other known suitable means. The means for moving the moveable platen may include means for ramping of the acceleration and deceleration movement and precision adjustments of speed and distances traveled.

Preferably, means for guiding the moveable platen are bearings on all four corners that mate with and travel along tracks attached to the frame to keep the moveable platen in precise alignment with the other platen. In the present preferred embodiment, the bearings are Linear Ball Slides manufactured by W. M. Berg, Inc. Such bearings are self cleaning and machined and constructed to relatively precise tolerances.

To further assist in maintaining the correct alignment between the moveable platen and the stationary platen, one platen may be provided with alignment means such as an alignment block or rod and the other platen may be adapted to receive such alignment means or may be provided with means, such as a socket, to receive such alignment means when the moveable platen is moved to a relatively closed position. The alignment means and receiving means should be constructed to relatively tight tolerances when the platens are in a relatively closed position and should be shaped to correct the position of the moveable platen as the platens move to a relatively closed position. One example of such a shape is a conical protrusion from one platen and a conical receiving socket attached to the other platen.

The travel of the moveable platen may be limited by physical stops at either end of the travel path. Alternatively, the travel may be limited by the means for moving the platen itself as described above or by some combination of the two. When the moveable platen is traveling from a relatively open position to a relatively closed position, shock absorbers or other resilient means may be used to slow the travel of the moveable platen before the spring biased probes make contact with the die to minimize the possibility of damage to the die and to minimize the possibility of the die being knocked out of alignment when the moving platen stops. Such shock absorbers or other resilient means should be located between the moveable platen and the stationary platen. The die may also be held in the proper position by a vacuum.

Preferably, the frame and platens are plated with a conductive material such as nickel and grounded to avoid any accumulation of static charge during the operation of the apparatus.

Preferably, a test socket frame is provided attached to the second probe card to create a test socket or nest for receiving and aligning the die. The test socket frame preferably is made from an insulating material to avoid any interference with the testing.

Preferably, the testing apparatus is designed with sufficient clearance between the platens when the platens are in a relatively open position to allow mechanized means such as a pickup head with specific pickup tips to place the die within the test nest and remove the die from the test nest.

In the operation of the preferred embodiment, the testing apparatus begins with the platens in a relatively open position. The die is placed into the test socket created by the second set of contact tooling or by a test socket frame and the second set of contact tooling. A vacuum is established to hold the die within the test socket and assist in making contact between the electrical contacts of the second set of contact tooling and the die. The moveable platen then begins to move toward a relatively closed position. The movement of the moveable platen may be controlled to vary the speed, acceleration, deceleration and distance traveled of the moveable platen. The shock absorbers or other resilient means make contact with stationary elements of the frame or the stationary platen and begin to slow the travel of the moveable platen. The alignment means begin to interlock and ensure that the moveable platen is aligned correctly. The electrical contacts of the first set of contact tooling make contact with the surface of the die and the moveable platen stops its travel in a relatively closed position. When the moveable platen is in a relatively closed position, the die may also be further compressed against the electrical contacts of the second set of contact tooling which may further assist the contact with the die.

The desired test signals are then sent and received through the first and test contact interface cards and the respective electrical contacts in the first and second sets of contact tooling. If it is determined that good contact has not been made with the die, the moveable platen can be moved back to a relatively open position to break the contact with the first set of contact tooling then returned to a relatively closed position pursuant to the foregoing procedure to reestablish contact between the die and the electrical contacts of the first and second sets of contact tooling.

Once the testing has been completed, the moveable platen then begins to travel from the relatively closed position to a relatively open position. The travel of the moveable platen is halted in a relatively open position. The tested die is removed from the test nest. A new die is inserted in the test nest and the foregoing procedure is repeated.

In one embodiment, the test contact tooling may be constructed of an array of spring biased probes contained within an insulating medium such as synthetic resinous material or other suitable material. One end of the probe contacts the surface of the die. The other end of the probe contacts the test contact interface card. Thus, varying the pattern of conductive traces on the test contact interface card places different probes and therefore different locations on the surface of the die in electrical contact with the test equipment.

One reasonably skilled in the art will recognize that other types of electrical contacts may be used to contact the surface of the die. For example, in the case of bumped die or fine pitch, epoxy ring mounted probe needles may be used. If such needles are used, the stopping point of the moveable platen must be calibrated or adjusted for the correct scrub. Other technologies may be employed for device contact requiring operation-specific test parameters.

### BRIEF DESCRIPTION OF THE DRAWINGS

FIG. 1 is a perspective view of an apparatus in accordance with one embodiment of the invention;

FIG. 2 is a front view of an apparatus in accordance with one embodiment of the invention;

FIG. 3 is a top view of an apparatus in accordance with one embodiment of the invention;

FIG. 4 is a side view of an apparatus in accordance with one embodiment of the invention;

FIG. 5 is a plan view of a first set of test contact tooling and a first test contact interface card in accordance with one embodiment of the invention;

FIG. 6 is a plan view of a second set of test contact tooling and a second test contact interface card in accordance with one embodiment of the invention;

FIG. 7 is an enlarged plan view of one embodiment of the test contact tooling consisting of an array of spring biased electrically conducting probes contained within an insulating medium;

FIG. 8 is a plan view of a second set of test contact tooling and a second test contact interface card in accordance with one embodiment of the invention;

FIG. 9 is an enlarged plan view of the one embodiment of the test contact tooling shown in FIG. 8 consisting of an array of spring biased electrically conducting probes contained within an insulating medium; and

FIG. 10 is a plan view of a first set of test contact tooling and a first test contact interface card in accordance with one embodiment of the invention.

### DETAILED DESCRIPTION OF THE PREFERRED EMBODIMENT

The following description is of the best presently contemplated modes of carrying out the invention. This description is made for the purpose of illustrating the general principals of the invention and should not be taken in a limiting sense.

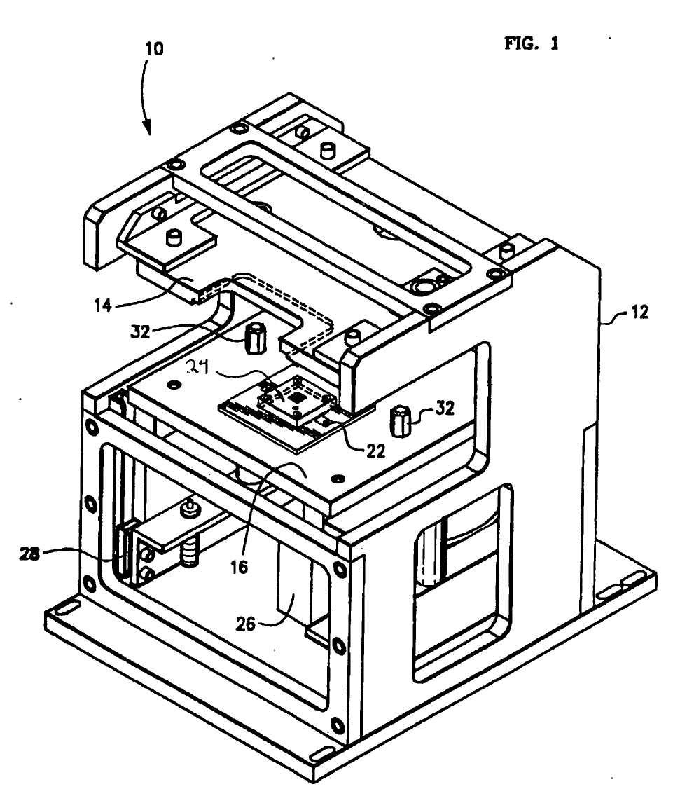

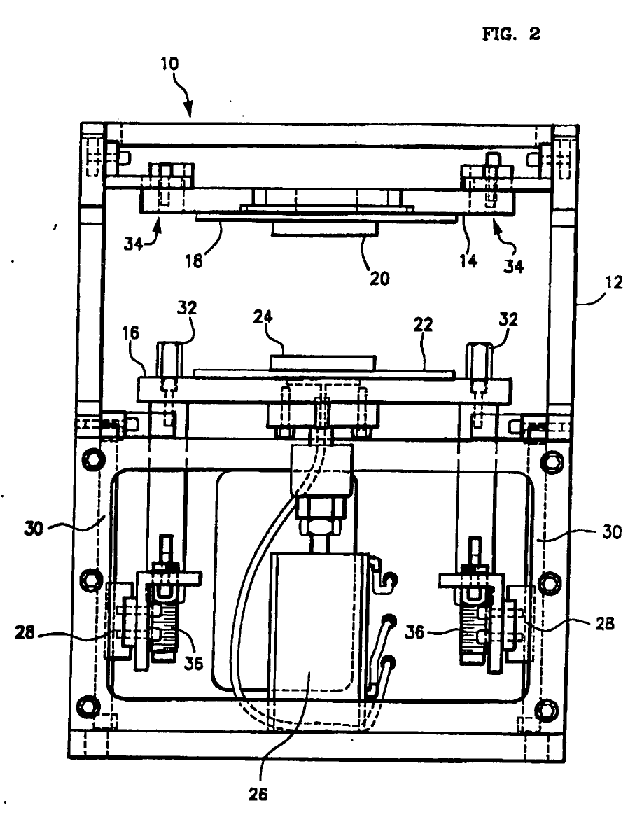

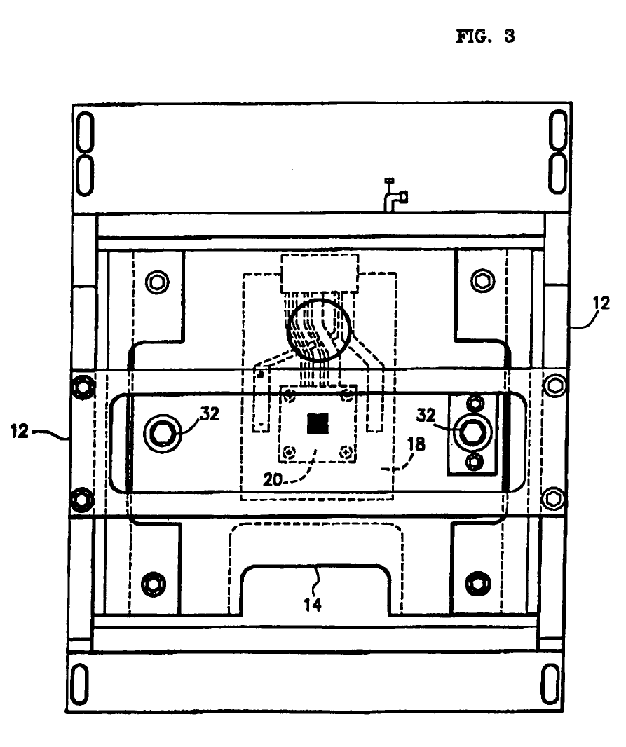

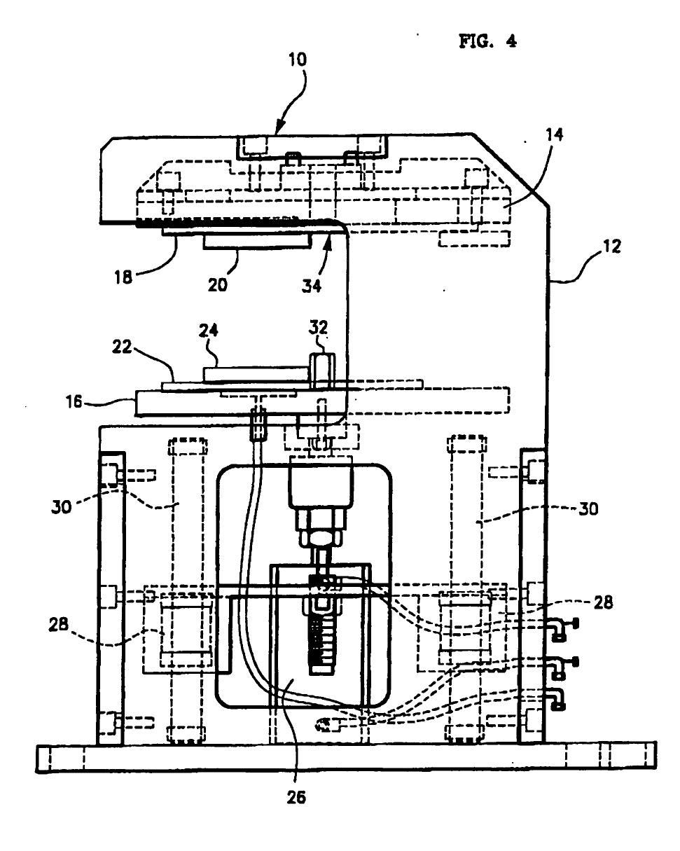

As shown in FIGS. 1, 2, 3 and 4 the testing apparatus designated generally as 10, comprises a frame 12, a first platen 14, a second platen 16 moveable with respect to said first platen, a first test contact interface card 18, a first set of test contact tooling 20, a second test contact interface card 22, a second set of test contact tooling 24, and a pancake lift 26 driven by compressed gas. The moveable platen 16 is guided by linear ball slides 28 that travel along tracks 30 which are attached to frame 12. When moveable platen 16 moves to a relatively closed position, alignment means 32 mate with receiving means 34 to further assist in making the correct alignment of test contact tooling 20 and 24. Shock absorbers 36 are provided to slow the travel of moveable platen 16 when it moves to a relatively closed position.

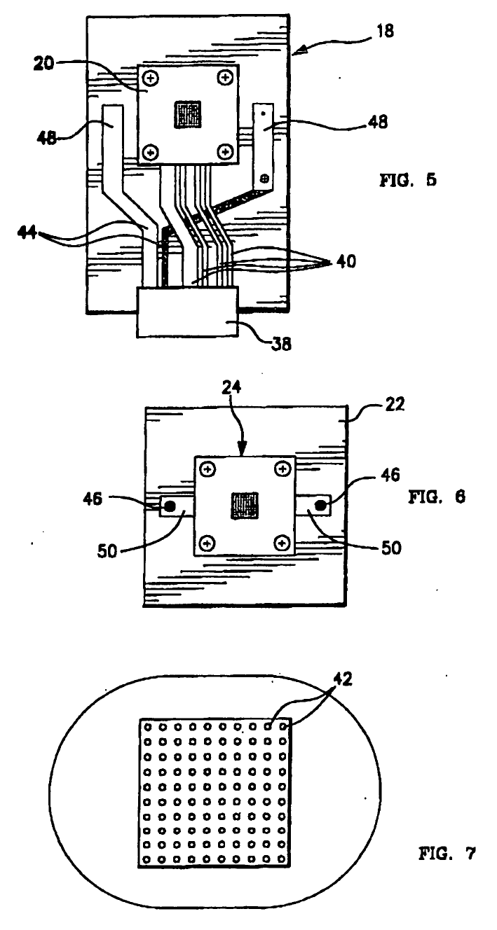

As shown in FIGS. 5 and 10, a first contact interface card 18 comprises means for connecting to test equipment (not shown) such as an edge connector 38, conductive traces collectively labeled 40 to carry the test signals between the test equipment and one or more electrical contacts 42 (shown in FIG. 7) contained in the first set of contact tooling 20, and conductive traces 44 to transmit power or test signals between the test equipment to contact pads 48 which contact the large spring biased contact probes 46 (shown in FIG. 6) when moveable platen 16 is in a relatively closed position.

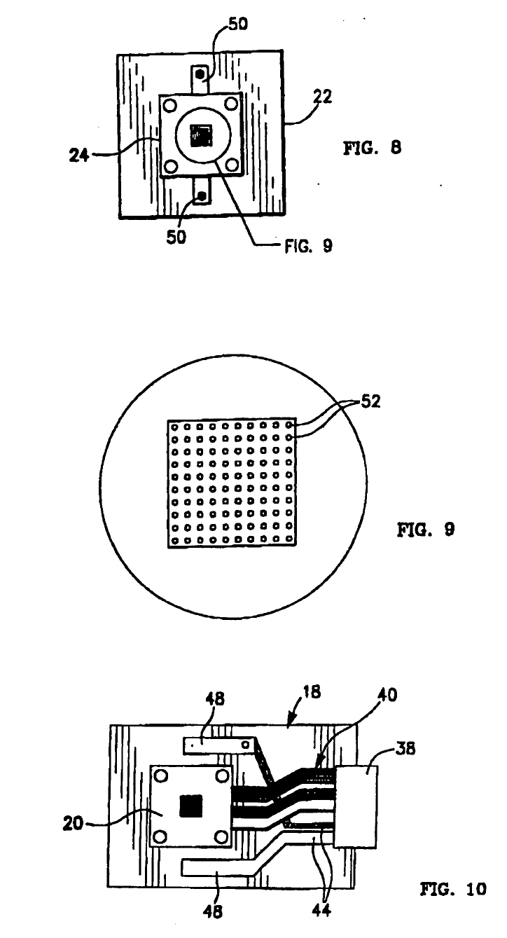

As shown in FIGS. 6 and 8, a second contact interface card 22 comprises conductive traces 50 to carry test signals or power between large spring biased contact probes 46 to one or more electrical contacts 52 (shown in FIG. 9) contained in the second set of contact tooling 24.

Although the invention has been described and illustrated with reference to specific embodiments thereof, it is not intended that the invention be limited to those illustrative embodiments. Those skilled in the art will recognize that modifications substitutions, deletions and variations can be made without departing from the spirit and scope of the invention. Therefore it is intended that this invention encompass all such variations and modifications as fall within the scope of the appended claims.

What is claimed is:

1. A singulated semiconductor die testing apparatus comprising:
a first and second contact interface card;
at least one of said interface cards adapted to be moveable with respect to the other between a relatively closed position and a relatively open position;
said first test contact interface card having at least a first and second electrically conductive trace adapted to establish electrical contact with test equipment;
a first set of test contact tooling attached to said first contact interface card between said first and second contact interface cards;
said first set of test contact tooling having at least one compliant electrical contact;
said compliant contact of said first set of test contact tooling electrically connected to said first conductive trace on said first contact interface card;
said compliant contact of said first set of test contact tooling adapted to contact a first surface of a singulated bare die and establish electrical contact between said first surface of said die and said first conductive trace when said first and second test contact interface cards are in a relatively closed position;
said second contact interface card having at least one conductive trace electrically connected to at least one spring biased electrical contact probe;
said spring biased electrical contact probe, said first contact interface card, said second contact interface card and said second electrically conductive trace on said first contact interface card adapted and aligned to establish electrical contact between said spring biased electrical contact probe and said second conductive trace on said first contact interface card when said first and second contact interface cards are in a relatively closed position;
a second set of test contact tooling attached to said second contact interface card between said first and second contact interface cards;
said second set of test contact tooling having at least one compliant electrical contact;
said compliant electrical contact of said second set of test contact tooling electrically connected to said conductive trace on said second contact interface card
said compliant electrical contact of said second set of test contact tooling adapted to contact a second surface of a singulated bare die and establish electrical contact between said second surface of said die and said conductive trace on said second contact interface card when said first and second contact interface cards are in a relatively closed position.

2. A singulated semiconductor die testing apparatus comprising:
a first and second contact interface card;
at least one of said interface cards adapted to be moveable with respect to the other between a relatively closed position and a relatively open position;
said first test contact interface card having at least a first and second electrically conductive trace adapted to establish electrical contact with test equipment;
a first set of test contact tooling attached to said first contact interface card between said first and second contact interface card;
said first set of test contact tooling having at least one compliant electrical contact;
said compliant contact of said first set of test contact tooling electrically connected to said first conductive trace on said first contact interface card;
said compliant contact of said first set of test contact tooling adapted to contact a first surface of a singulated bare die and establish electrical contact between said first surface of said die and said first conductive trace when said first and second test contact interface cards are in a relatively closed position;
a spring biased electrical contact probe electrically connected to said second electrically conductive trace on said first contact interface card;
said second contact interface card having at least one conductive trace;
said spring biased electrical contact probe, said first contact interface card, said second contact interface card and said electrically conductive trace on said second contact interface card adapted and aligned to establish electrical contact between said spring biased electrical contact probe and said electrically conductive trace on said second contact interface card when said first and second contact interface cards are in a relatively closed position;
a second set of test contact tooling attached to said second contact interface card between said first and second contact interface cards;
said second set of test contact tooling having at least one compliant electrical contact;
said compliant electrical contact of said second set of test contact tooling electrically connected to said conductive trace on said second contact interface card
said compliant electrical contact of said second set of test contact tooling adapted to contact a second surface of a singulated bare die and establish electrical contact between said second surface of said die and said conductive trace on said second contact interface card when said first and second contact interface cards are in a relatively closed position.

3. The singulated semiconductor die testing apparatus of claim 1 further comprising:
a first platen;
said first test contact interface card attached to said first platen;
a second platen;
said second test contact interface card attached to said second platen;
at least one of said platens adapted to be moveable with respect to the other between a relatively open position and a relatively closed position;
means for moving said moveable platen;
a frame for supporting said first platen, said second platen and said means for moving.

4. The singulated semiconductor die testing apparatus of claim 3 wherein said frame includes means for guiding said moveable platen.

5. The singulated semiconductor die testing apparatus of claim 3 further comprising:
at least one track attached to said frame;
at least one linear ball slide attached to said moveable platen and said track to guide said moveable platen.

6. The singulated semiconductor die testing apparatus of claim 3 further comprising means for controlling a length of travel of said moveable platen;

7. The singulated semiconductor die testing apparatus of claim 3 further comprising means for adjusting an acceleration of said moveable platen;

8. The singulated semiconductor die testing apparatus of claim 3 further comprising means for adjusting a deceleration of said moveable platen;

9. The singulated semiconductor die testing apparatus of claim 3 further comprising means for aligning said first and second platens with respect to each other when said first and second platens are approaching a relatively closed position.

10. The singulated semiconductor die testing apparatus of claim 3 wherein at least a portion of said frame is electrically conductive.

11. The singulated semiconductor die testing apparatus of claim 2 further comprising:
a first platen;
said first test contact interface card attached to said first platen;
a second platen;
said second test contact interface card attached to said second platen;
at least one of said platens adapted to be moveable with respect to the other between a relatively open position and a relatively closed position;
means for moving said moveable platen;
a frame for supporting said first platen, said second platen and said means for moving.

12. The singulated semiconductor die testing apparatus of claim 11 wherein said frame includes means for guiding said moveable platen.

13. The singulated semiconductor die testing apparatus of claim 11 further comprising:
at least one track attached to said frame;
at least one linear ball slide attached to said moveable platen and said track to guide said moveable platen.

14. The singulated semiconductor die testing apparatus of claim 11 further comprising means for controlling a length of travel of said moveable platen;

15. The singulated semiconductor die testing apparatus of claim 11 further comprising means for adjusting an acceleration of said moveable platen;

16. The singulated semiconductor die testing apparatus of claim 11 further comprising means for adjusting a deceleration of said moveable platen;

17. The singulated semiconductor die testing apparatus of claim 11 further comprising means for aligning said first and second platens with respect to each other when said first and second platens are approaching a relatively closed position.

18. The singulated semiconductor die testing apparatus of claim 11 wherein at least a portion of said frame is electrically conductive.
